(19) United States
(12) Patent Application Publication
(10) Pub. No.: US 2024/0347248 A1
(43) Pub. Date: Oct. 17, 2024

(54) SUPERCONDUCTING MAGNET DEVICE

(71) Applicant: JAPAN SUPERCONDUCTOR TECHNOLOGY INC., Hyogo (JP)

(72) Inventors: Takuya MATSUMOTO, Kobe-Shi (JP); Hideaki NAGAHAMA, Kobe-Shi (JP); Satoshi ITO, Kobe-Shi (JP)

(73) Assignee: JAPAN SUPERCONDUCTOR TECHNOLOGY INC., Hyogo (JP)

(21) Appl. No.: 18/626,360

(22) Filed: Apr. 4, 2024

(30) Foreign Application Priority Data
Apr. 12, 2023 (JP) 2023-065002

(51) Int. Cl. H01F 6/04; F25D 19/00; G01R 33/3815

(52) U.S. Cl. CPC H01F 6/04; F25D 19/006; G01R 33/3815

(57) ABSTRACT

A superconducting magnet device includes a magnet device body including a superconducting magnet, a magnet support, a refrigerator, a refrigerator support, and a coupling member. The magnet support supports the magnet device body such that the magnet device body is disposed above an installation surface. The refrigerator support supports the refrigerator from below such that the refrigerator is disposed above the installation surface. The coupling member couples the refrigerator support and the magnet support at a position above the installation surface.

### FIELD OF INVENTION

The present invention relates to a superconducting magnet device including a refrigerator.

### BACKGROUND ART

For example, JP 2007-051850 A describes a conventional superconducting magnet device. The device described in JP 2007-051850 A includes a magnet device body (NMR in JP 2007-051850 A) that measures a sample and a refrigerator that cools a refrigerant (helium and nitrogen in JP 2007-051850 A) for cooling a superconducting magnet.

When the refrigerator as described above vibrates, there is a possibility that the vibration is transmitted to the magnet device body and affects the measurement in the magnet device body.

### SUMMARY OF THE INVENTION

An object of the present invention is to provide a superconducting magnet device capable of suppressing vibration that affects measurement in a magnet device body.

The superconducting magnet device includes the magnet device body, a magnet support, a refrigerator, a refrigerator support, and at least one coupling member. The magnet device body includes a superconducting magnet. The magnet support supports the magnet device body such that the magnet device body is disposed above an installation surface. The refrigerator is disposed at a position away from the magnet device body and cools a refrigerant that cools the superconducting magnet. The refrigerator support supports the refrigerator from below such that the refrigerator is disposed above the installation surface. The coupling member couples the refrigerator support and the magnet support at a position above the installation surface.

### BRIEF DESCRIPTION OF THE DRAWINGS

FIG. 1 is a cross-sectional view of a superconducting magnet device according to an embodiment of the present invention.

FIG. 2 is a cross-sectional view of a superconducting magnet device including a magnet support disposed at a position different from a magnet support illustrated in FIG. 1.

### DETAILED DESCRIPTION

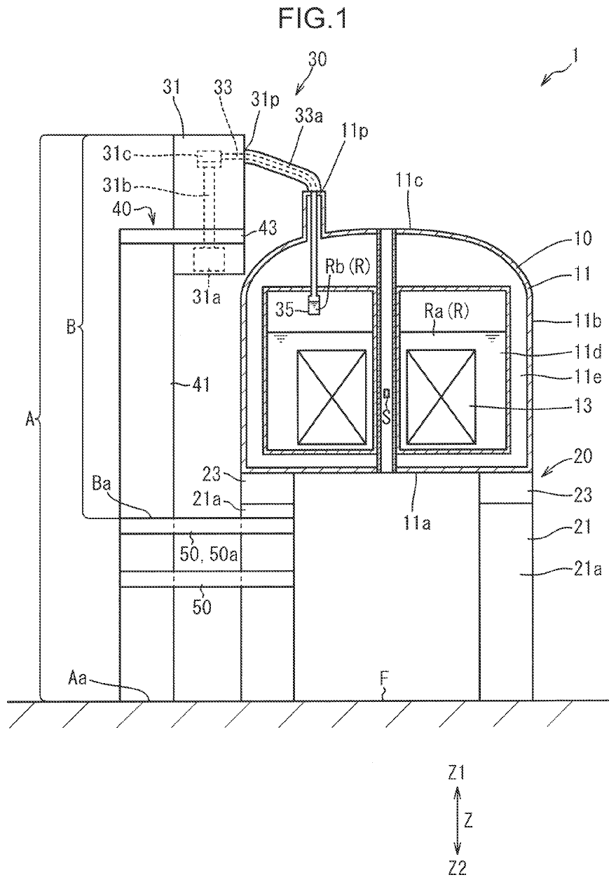

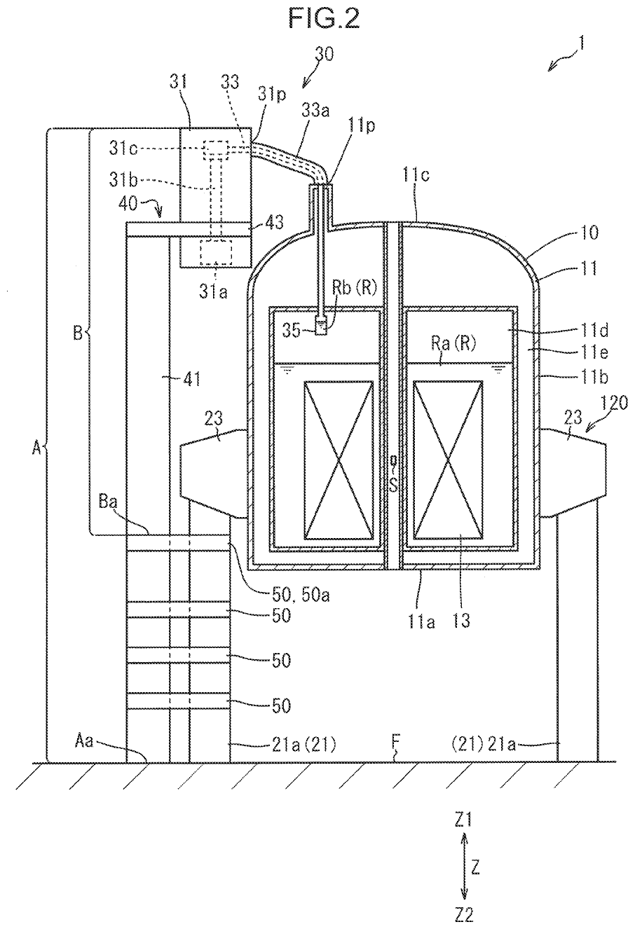

A superconducting magnet device 1 according to an embodiment of the present invention will be described with reference to FIGS. 1 and 2. FIG. 1 is a cross-sectional view of the superconducting magnet device 1 according to the present embodiment. FIG. 2 is a cross-sectional view of the superconducting magnet device 1 including a magnet support disposed at a position different from a magnet support illustrated in FIG. 1. FIGS. 1 and 2 illustrate an inside of a magnet device body 10 described later in cross section.

As illustrated in FIG. 1, the superconducting magnet device 1 includes a superconducting magnet 13. The superconducting magnet device 1 is a device (NMR device) for measuring a sample S by using nuclear magnetic resonance (NMR) (NMR measurement). The superconducting magnet device 1 includes a magnet device body 10, a magnet support 20, a refrigerant evaporation suppression device 30, a refrigerator support 40, and a coupling member 50.

The magnet device body 10 is a body of the superconducting magnet device 1. The magnet device body 10 includes a cryostat 11 and the superconducting magnet 13.

The cryostat 11 is a container for bringing the superconducting magnet 13 into a low temperature state. The cryostat 11 accommodates the superconducting magnet 13 and cools the superconducting magnet 13. Here, a vertical direction or a substantially vertical direction is defined as an up-down direction Z. An upward direction in the vertical direction or the substantially vertical direction is defined as an upward direction Z1, and a direction opposite to the upward direction Z1 is defined as a downward direction Z2. The outer shape of the cryostat 11 is, for example, a substantially cylindrical shape. For example, when viewed along the up-down direction Z, the cryostat 11 is circular, substantially circular, or the like. The cryostat 11 has a bottom surface 11a, a side surface 11b, and an upper surface 11c constituting an outer surface of the cryostat 11. The cryostat 11 further includes a refrigerant tank 11d, a vacuum tank 11e, and a magnet side connection portion 11p.

The bottom surface 11a constitutes a lower surface of the cryostat 11 and includes a surface facing the downward direction Z2. The side surface 11b includes a surface (peripheral surface) of the cryostat 11 facing a lateral direction (direction intersecting the up-down direction Z). When the cryostat 11 is substantially cylindrical, the side surface 11b includes a surface facing outward in a radial direction of the cryostat 11. The upper surface 11c constitutes an upper surface of the cryostat 11 and includes a surface facing the upward direction Z1.

The refrigerant tank 11d is a tank that stores a refrigerant R (for example, a cooling refrigerant Ra) described later. Only one refrigerant tank 11d may be provided as in the example illustrated in FIG. 1, or a plurality of refrigerant tanks 11d may be provided (not illustrated). For example, when a plurality of refrigerant tanks 11d are provided, one refrigerant tank 11d that accommodates the superconducting magnet 13 and another refrigerant tank 11d disposed outside (a side far from the superconducting magnet 13, for example, a radially outer side, or the like) of the refrigerant tank 11d may be provided.

The vacuum tank 11e is a tank in a vacuum state. The vacuum tank 11e is disposed outside the refrigerant tank 11d (on the side far from the superconducting magnet 13). Note that the cryostat 11 may include components (for example, a radiation shield or the like) for keeping the superconducting magnet 13 cool, in addition to the refrigerant tank 11d and the vacuum tank 11e.

The magnet side connection portion 11p is a part (port) to which an exposed portion 33a (described later) of a refrigerant circulation pipe 33 is connected. The magnet side connection portion 11p protrudes in the upward direction Z1 from the upper surface 11c. The magnet side connection portion 11p is formed integrally with the upper surface 11c, for example.

The superconducting magnet 13 is a magnet that generates a strong magnetic field. The superconducting magnet 13 includes a coil around which a superconducting wire material is wound. The superconducting magnet 13 is accommodated in the cryostat 11 and accommodated in the refrigerant tank 11d. The superconducting magnet 13 is brought into a low temperature state by the cryostat 11 and is brought into a superconducting state.

The magnet support 20 supports the magnet device body 10. The magnet support 20 supports the magnet device body 10 such that the magnet device body 10 is disposed above an installation surface F. The installation surface F is a surface on which the superconducting magnet device 1 is installed, and is, for example, a floor surface. The magnet support 20 supports the magnet device body 10 with the installation surface F as a reference. Specifically, the magnet support 20 is disposed so as to extend in the upward direction Z1 from the installation surface F. In the example illustrated in FIG. 1, the magnet support 20 is attached to the bottom surface 11a and fixed to the bottom surface 11a. As in the example illustrated in FIG. 2, the magnet support 20 may be attached to the side surface 11b and fixed to the side surface 11b (see a magnet support 120 in FIG. 2).

As illustrated in FIG. 1, the magnet support 20 is preferably configured to reduce vibration transmitted from the installation surface F to the magnet device body 10. The magnet support 20 is preferably, for example, a vibration isolator. Specifically, the magnet support 20 includes a magnet support body 21 and a vibration damper 23.

Specifically, the magnet support body 21 is provided so as to extend in the upward direction Z1 from the installation surface F. The magnet support body 21 is fixed to the installation surface F, for example. The magnet support body 21 may directly contact the installation surface F, or may be placed on the installation surface F with a member (for example, rubber) separate from the magnet support body 21 interposed therebetween. The shape of the magnet support body 21 can be variously set. For example, the shape of the magnet support body 21 may be a shape including a leg 21a, may be a table shape including the leg 21a, or may be a shape (for example, a box shape) not including the leg 21a.

The leg 21a is a columnar member. The leg 21a may have, for example, a cylindrical shape or a columnar shape (for example, a quadrangular prism shape) having a polygonal cross section. In the present embodiment, a plurality of legs 21a is provided. For example, three legs 21a may be provided, or four or more legs 21a may be provided.

The vibration damper 23 is a device that reduces vibration transmitted from the magnet support body 21 to the magnet device body 10. The vibration damper 23 attenuates the vibration and substantially blocks the vibration. As a result of reducing the vibration, the vibration damper 23 reduces vibration transmitted from the installation surface F to the magnet device body 10. As a result of reducing the vibration transmitted from the magnet support body 21 to the magnet device body 10, the vibration damper 23 reduces vibration transmitted from the coupling member 50 to the magnet device body 10. The vibration damper 23 is disposed between the magnet support body 21 and the magnet device body 10 (in a path through which the vibration is transmitted). The vibration damper 23 is disposed between the coupling member 50 (described later) and the magnet device body 10. The Vibration damper 23 is connected to, for example, an upper end of the magnet support body 21. The vibration damper 23 may be connected to the bottom surface 11a or may be connected to the side surface 11b (see FIG. 2).

The vibration damper 23 may include a device that reduces vibration by utilizing a fluid. For example, the vibration damper 23 may include a device (such as an air damper) that uses the pressure of the fluid, or may include a device (such as an oil damper) that uses the viscous resistance of the fluid. The vibration damper 23 may include a device that reduces vibration by utilizing deformation of an elastic member (rubber, elastomer, or the like).

The refrigerant evaporation suppression device 30 prevents evaporation of the refrigerant R. The refrigerant evaporation suppression device 30 includes a refrigerator 31, a heat exchanger 35, and a refrigerant circulation pipe 33.

### <Refrigerant R>

The refrigerant R cools the superconducting magnet 13. For example, the refrigerant R includes a cooling refrigerant Ra and a heat exchanging refrigerant Rb. The cooling refrigerant Ra is put into the refrigerant tank 11d to cool the superconducting magnet 13. Only one type of cooling refrigerant Ra may be used, or a plurality of types of refrigerants Ra may be used. When only one type of cooling refrigerant Ra is used, the refrigerant Ra is specifically liquid helium.

When a plurality of types of cooling refrigerant Ra is used, the cooling refrigerants Ra include a main refrigerant and an auxiliary refrigerant. The main refrigerant is put into the refrigerant tank 11d which accommodates the superconducting magnet 13. The main refrigerant is specifically liquid helium. The auxiliary refrigerant is put into another refrigerant tank 11d (not illustrated) provided outside the refrigerant tank 11d that accommodates the superconducting magnet 13. The auxiliary refrigerant may be, for example, liquid nitrogen or liquid argon.

The heat exchanging refrigerant Rb is a refrigerant R for cooling the cooling refrigerant Ra and condensing (liquefying) the cooling refrigerant Ra (details will be described later). Similarly to the cooling refrigerant Ra, only one type of heat exchanging refrigerant Rb may be used, or a plurality of types of heat exchanging refrigerants Rb may be used. Note that only the cooling refrigerant Ra may be used, and the heat exchanging refrigerant Rb is not required to be used (the heat exchanger 35 is not required to be used). Hereinafter, a case where the heat exchanging refrigerant Rb is used will be mainly described.

The refrigerator 31 cools the refrigerant R (for example, the heat exchanging refrigerant Rb). The refrigerator 31 cools the refrigerant R in a condensation chamber 31c (described later) by cold heat generated by adiabatic expansion of a refrigerant for refrigeration. Note that the “refrigerant for refrigeration” is not included in the refrigerant R for cooling the superconducting magnet 13. The refrigerator 31 is a cryogenic refrigerator, and may be, for example, a Gifford-McMahon refrigerator, a pulse tube refrigerator, or another cryogenic refrigerator.

The refrigerator 31 is preferably disposed so as to suppress transmission of vibration of the refrigerator 31 to the magnet device body 10. Specifically, the refrigerator 31 is disposed at a position away from (a position spaced apart from) the magnet device body 10. The refrigerator 31 is disposed at such a position as not to be in direct contact with the magnet device body 10. Note that the arrangement (height) of the refrigerator 31 in the up-down direction Z will be described later. The refrigerator 31 includes a drive unit 31a, a piston 31b, a condensation chamber 31c, and a refrigerator side connection portion 31p.

The drive unit 31a is a device that drives the piston 31b. The drive unit 31a is, for example, a motor. The drive unit 31a is preferably disposed in a lower part of the refrigerator 31 (described later). The piston 31b thermally insulates and expands the refrigerant for refrigeration. The condensation chamber 31c is a part (space) that condenses the evaporated refrigerant R. The refrigerator side connection portion 31p is a part (port) to which an exposed portion 33a (described later) of a refrigerant circulation pipe 33 is connected.

The refrigerant circulation pipe 33 is a pipe through which the refrigerant R (for example, the heat exchanging refrigerant Rb) passes. The refrigerant circulation pipe 33 is configured to allow the refrigerant R to move back and forth between the magnet device body 10 and the refrigerator 31. The refrigerant circulation pipe 33 is connected to the magnet device body 10 and the refrigerator 31. Specifically, the refrigerant circulation pipe 33 is connected to the heat exchanger 35 inside the magnet device body 10 and the condensation chamber 31c inside the refrigerator 31. The refrigerant circulation pipe 33 extends in the downward direction Z2 from the condensation chamber 31c toward the heat exchanger 35 (described later). The condensed refrigerant R (liquid) and the evaporated refrigerant R (gas) pass through the refrigerant circulation pipe 33. Specifically, the condensed refrigerant R passing through the refrigerant circulation pipe 33 is the refrigerant R condensed by the refrigerator 31 (for example, the heat exchanging refrigerant Rb), and is the refrigerant R flowing from the refrigerator 31 to the magnet device body 10. The evaporated refrigerant R passing through the refrigerant circulation pipe 33 is refrigerant R (for example, the heat exchanging refrigerant Rb) evaporated inside the magnet device body 10, and is refrigerant R flowing from the magnet device body 10 to the refrigerator 31. The refrigerant circulation pipe 33 may include (separately) a pipe through which the condensed refrigerant R passes and a pipe through which the evaporated refrigerant R passes. For example, the refrigerant circulation pipe 33 may include a double pipe or two pipes. Alternatively, the refrigerant circulation pipe 33 may include only one pipe. The condensed refrigerant R and the evaporated refrigerant R may pass through the refrigerant circulation pipe 33 which is one pipe. The refrigerant circulation pipe 33 has the exposed portion 33a.

The exposed portion 33a is disposed outside the refrigerator 31 and outside the magnet device body 10. The exposed portion 33a is connected to the magnet side connection portion 11p and the refrigerator side connection portion 31p. The exposed portion 33a is deformable within a predetermined range (deformable range) and is bendable within a predetermined range (has flexibility). As a result, the vibration transmitted from the refrigerator 31 to the magnet device body 10 through the exposed portion 33a is suppressed.

The heat exchanger 35 exchanges heat between the cooling refrigerant Ra and the heat exchanging refrigerant Rb. The heat exchanger 35 is disposed inside the magnet device body 10. The heat exchanger 35 is disposed inside the refrigerant tank 11d. The heat exchanger 35 is disposed above a liquid level of the cooling refrigerant Ra. The heat exchanger 35 has, for example, a substantially cylindrical shape with a hollow inside.

The heat exchange and the like in the heat exchanger 35 are performed as follows. The heat exchanging refrigerant Rb (liquid) condensed in the condensation chamber 31c passes through the refrigerant circulation pipe 33 and enters the inside of the heat exchanger 35. A part of the cooling refrigerant Ra evaporates inside the refrigerant tank 11d. The evaporated cooling refrigerant Ra comes into contact with an outer surface of the heat exchanger 35 to be cooled and condensed. The condensed cooling refrigerant Ra falls to the liquid level inside the refrigerant tank 11d and is stored in the refrigerant tank 11d. The heat exchanging refrigerant Rb inside the heat exchanger 35 is evaporated by heat transferred from the cooling refrigerant Ra through the heat exchanger 35. The evaporated heat exchanging refrigerant Rb (gas) passes through the refrigerant circulation pipe 33 and returns to the condensation chamber 31c.

### <Arrangement of Refrigerator 31 and the Like>

The refrigerator 31 is preferably disposed so as to utilize natural circulation of the gas-liquid refrigerant R. Specifically, the refrigerator 31 is preferably disposed at a height (position in the up-down direction Z) that allows the refrigerant R (liquid) condensed by the refrigerator 31 to flow from the refrigerator 31 into the magnet device body 10 through the refrigerant circulation pipe 33 by the weight of the refrigerant R. This arrangement eliminates the need for providing a pump that forcibly flows the refrigerant R condensed by the refrigerator 31 from the refrigerator 31 to the inside of the magnet device body 10. As a result, it is possible to prevent vibration generated by the pump from being transmitted to the magnet device body 10.

Specifically, the refrigerator 31 is preferably disposed at a height that allows the heat exchanging refrigerant Rb (liquid) condensed in the condensation chamber 31c to flow from the condensation chamber 31c to the heat exchanger 35 through the refrigerant circulation pipe 33 by the weight of the heat exchanging refrigerant Rb. More specifically, the condensation chamber 31c is preferably disposed above the heat exchanger 35. The refrigerator side connection portion 31p is preferably disposed above the magnet side connection portion 11p. The refrigerant circulation pipe 33 preferably extends downward from the condensation chamber 31c toward the heat exchanger 35. The exposed portion 33a preferably extends downward from the refrigerator side connection portion 31p toward the magnet side connection portion 11p. The refrigerant circulation pipe 33 may have a linearly extending portion or a curvilinear extending portion. A part of the refrigerant circulation pipe 33 may extend in a horizontal direction (this case is also included in the “extending downward” described above).

The refrigerator 31 is preferably disposed at a position as low as possible (lower position). By arranging the refrigerator 31 at a position as low as possible, a length of a beam B (described later) can be reduced. Specifically, for example, the drive unit 31a is preferably disposed below the condensation chamber 31c. In this case, the refrigerator 31 can be disposed at a lower position than in a case where the drive unit 31a is disposed above the condensation chamber 31c. For example, the drive unit 31a is preferably disposed in a lower part of the refrigerator 31. The drive unit 31a is preferably disposed below the piston 31b. For example, a lower end (for example, the drive unit 31a) of the refrigerator 31 is preferably disposed below an upper end of the upper surface 11c of the cryostat 11.

The refrigerator support 40 supports the refrigerator 31 such that the refrigerator 31 is disposed above the installation surface F. The refrigerator support 40 preferably supports the refrigerator 31 such that the condensation chamber 31c is disposed above the heat exchanger 35. The refrigerator support 40 supports the refrigerator 31 from below. Specifically, the refrigerator support 40 is disposed to so as to extend upward from a position below the position of the refrigerator 31. The refrigerator support 40 is disposed at a position away from (a position spaced apart from) the magnet device body 10. The refrigerator support 40 is disposed at such a position as not to be in direct contact with the magnet device body 10. The refrigerator support 40 is disposed at an interval in the horizontal direction from the magnet device body 10. The refrigerator support 40 includes a refrigerator support body 41 and a refrigerator attachment portion 43.

The refrigerator support body 41 is a body of the refrigerator support 40. The refrigerator support body 41 is disposed to so as to extend upward from a position below the position of the refrigerator 31. For example, the refrigerator support body 41 is disposed so as to extend upward from the installation surface F. The refrigerator support body 41 is fixed to the installation surface F, for example. The refrigerator support body 41 may directly contact the installation surface F, or may be placed on the installation surface F with a member (for example, rubber) separate from the refrigerator support body 41 interposed therebetween. The refrigerator support body 41 is not required to be provided so as to extend upward from the installation surface F, and may be provided so as to extend upward from the coupling member 50, for example. The refrigerator support body 41 includes a columnar member. The refrigerator support body 41 may have, for example, a cylindrical shape or a columnar shape (for example, a quadrangular prism shape) having a polygonal cross section. In the present embodiment, only one refrigerator support body 41 is provided. A plurality of refrigerator support body 41 may be provided (not illustrated). The refrigerator attachment portion 43 is a part to which the refrigerator 31 is attached. The refrigerator attachment portion 43 holds the refrigerator 31 on the refrigerator support body 41.

The coupling member 50 suppresses vibration of the beam B (described later) including the refrigerator support 40 and the refrigerator 31. The coupling member 50 couples the refrigerator support 40 and the magnet support 20 at a position above the installation surface F (details will be described later). When a plurality of coupling members 50 is provided (described later), the coupling member 50 disposed on an uppermost side is referred to as an uppermost coupling member 50a.

### <Vibration>

Here, a case where no coupling member 50 is provided will be considered. In this case, the refrigerator 31 disposed at a position higher than the installation surface F serves as a vibration source, and the entire refrigerator support 40 and the entire refrigerator 31 vibrate. At this time, the refrigerator support 40 and the refrigerator 31 constitute a cantilever beam (beam A) having the installation surface F as a fixing point Aa. The longer a length of the beam A (a length in the up-down direction Z), the larger an amplitude of the vibration of the beam A, and the lower a natural frequency of the beam A. The vibration of the beam A is transmitted to the magnet device body 10 through the refrigerant circulation pipe 33 and the installation surface F. The vibration transmitted to the magnet device body 10 affects the measurement (NMR measurement) of the sample S in the magnet device body 10, and specifically, appears as noise. In particular, vibration at a low frequency (for example, 10 Hz or less) transmitted to the magnet device body 10 has a large influence on the NMR measurement.

Therefore, the coupling member 50 suppresses vibration of an entirety (the beam A) of the refrigerator support 40 and the refrigerator 31. Specifically, the coupling member 50 couples the refrigerator support 40 and the magnet support 20 at a position above the installation surface F. As a result, a part of the refrigerator support 40 above the coupling member 50 and the refrigerator 31 constitute a cantilever beam (beam B). A height (position in the up-down direction Z) of a fixing point Ba of the beam B is a height of the coupling member 50 and is above the fixing point Aa. When the plurality of coupling members 50 is provided, the height of the fixing point Ba is a height of the uppermost coupling member 50a. By providing the coupling member 50, the length of the beam B becomes shorter than the length of the beam A. Therefore, an amplitude of vibration in the beam B is smaller than the amplitude of vibration in the beam A. Therefore, the amplitude of vibration transmitted from the beam B to the magnet device body 10 is suppressed. In addition, since the length of the beam B is shorter than the length of the beam A, a natural frequency of the beam B is higher than the natural frequency of the beam A. Therefore, a low frequency transmitted from the beam B to the magnet device body 10 is suppressed. As a result, the influence on the measurement of the sample S in the magnet device body 10 is suppressed.

The coupling member 50 is connected to the refrigerator support 40. Specifically, the coupling member 50 is connected to the refrigerator support body 41. The coupling member 50 is fixed to the refrigerator support body 41. The coupling member 50 may be detachably fixed to the refrigerator support body 41 by a fastening member or the like, or may be fixed to the refrigerator support body 41 by welding or the like.

The coupling member 50 is connected to the magnet support 20. Specifically, the coupling member 50 is connected to the magnet support body 21. For example, when the magnet support body 21 includes the leg 21a, the coupling member 50 is connected to the leg 21a. When a plurality of legs 21a is provided, the coupling member 50 may be connected to only one leg 21a or may be connected to the plurality of legs 21a. The coupling member 50 is fixed to the magnet support body 21. The coupling member 50 may be detachably fixed to the magnet support body 21 by a fastening member or the like, or may be fixed to the magnet support body 21 by welding or the like. When the magnet support 20 includes the vibration damper 23, the coupling member 50 is connected to the magnet support body 21 at a position of the vibration damper 23 opposite to the magnet device body 10. Specifically, the coupling member 50 is connected to the magnet support body 21 at a position below the vibration damper 23.

The coupling member 50 is disposed so as to extend in the horizontal direction, for example. Specifically, the coupling member 50 may have a plate shape or the like provided so as to extend in the horizontal direction. Note that the coupling member 50 may be inclined with respect to the horizontal direction. The coupling member 50 is not required to have a plate shape, may have a rod shape, a block shape, or the like.

The coupling member 50 is preferably disposed at a position as high as possible (upper position). When the plurality of coupling members 50 is provided, the uppermost coupling member 50a is preferably disposed at a position (upper position) as high as possible. By arranging the coupling member 50 at a position as high as possible, the fixing point Ba is disposed further on an upper position, and the beam B is shortened. As a result, the amplitude of the beam B is further reduced, and the natural frequency of the beam B is further increased. In the example illustrated in FIGS. 1 and 2, the coupling member 50 (for example, uppermost coupling member 50a) is disposed below the vibration damper 23 and near the vibration damper 23. In the example illustrated in FIG. 2, the coupling member 50 (for example, the uppermost coupling member 50a) is disposed above the bottom surface 11a of the magnet device body 10. Specifically, for example, the coupling member 50 is disposed at a position about 1 m higher than the installation surface F.

Note that a plurality of coupling members 50 may be provided. In this case, the plurality of coupling members 50 are disposed apart from each other in the up-down direction Z. In the example illustrated in FIG. 1, two coupling members 50 are provided, and in the example illustrated in FIG. 2, four coupling members 50 are provided. Three coupling members 50 may be provided, and five or more coupling members 50 may be provided. By providing the plurality of coupling members 50, the magnet support 20, the plurality of coupling members 50, and the refrigerator support 40 are integrally coupled and fixed. Accordingly, rigidity of the magnet support 20, the refrigerator support 40, and the plurality of coupling members 50 as a whole is improved (deformation is suppressed). As a result, the vibration of the beam B is suppressed, and the vibration of the magnet device body 10 is suppressed.

The superconducting magnet device 1 illustrated in FIG. 1 has the following effects. The superconducting magnet device 1 includes the magnet device body 10 including the superconducting magnet 13, the magnet support 20, the refrigerator 31, the refrigerator support 40, and the coupling member 50. The magnet support 20 supports the magnet device body 10 from the installation surface F such that the magnet device body 10 is disposed above an installation surface F.

[Configuration 1-1] The refrigerator 31 is disposed at a position away from the magnet device body 10, and cools the refrigerant R that cools the superconducting magnet 13. The refrigerator support 40 supports the refrigerator 31 from below such that the refrigerator 31 is disposed above the installation surface F.

[Configuration 1-2] The coupling member 50 couples the refrigerator support 40 and the magnet support 20 at a position above the installation surface F.

In [Configuration 1-1], the refrigerator support 40 and the refrigerator 31 constitute a cantilever beam (the beam B). In [Configuration 1-2], the position of the coupling member 50 (the uppermost coupling member 50a in the example of FIG. 1) above the installation surface F can be set as the fixing point Ba of the beam B. Therefore, a height of the fixing point Ba when the coupling member 50 is provided can be made higher (upward) than a height of the fixing point Aa when the coupling member 50 is not provided (the position in the up-down direction Z). Therefore, the length of the beam B (the length in the up-down direction Z) can be reduced. Therefore, the amplitude of the vibration of the beam B can be suppressed. As a result, the amplitude of vibration transmitted to the magnet device body 10 can be suppressed. In addition, since the length of the beam B can be reduced, the natural frequency of the beam B can be increased. Accordingly, vibration at a low frequency (for example, 10 Hz or less) transmitted to the magnet device body 10 can be suppressed. Therefore, the superconducting magnet device 1 can suppress vibration that affects measurement (measurement of the sample S) in the magnet device body 10.

The superconducting magnet device 1 includes the refrigerant circulation pipe 33. The refrigerant R passes through the refrigerant circulation pipe 33. The refrigerant circulation pipe 33 is connected to the magnet device body 10 and the refrigerator 31.

[Configuration 2] The refrigerator 31 is disposed at a height that allows the refrigerant R condensed by the refrigerator 31 to flow from the refrigerator 31 into the magnet device body 10 through the refrigerant circulation pipe 33 by the weight of the refrigerant R.

In [Configuration 2] described above, the refrigerator 31 is disposed at a high position (upper position) where the refrigerant R flows from the refrigerator 31 into the magnet device body 10 by the weight of the refrigerant R. Therefore, the refrigerator support 40 that supports the refrigerator 31 tends to be long in the up-down direction Z, and the beam B tends to be long. Therefore, if the coupling member 50 is not provided, there is a possibility that vibration that affects measurement in the magnet device body 10 becomes a problem. However, in the superconducting magnet device 1, the beam B can be shortened by the coupling member 50 of [Configuration 1]. Therefore, the superconducting magnet device 1 can suppress vibration that affects the measurement in the magnet device body 10 even when the refrigerator 31 is disposed at the height as in [Configuration 2].

The magnet support 20 includes the magnet support body 21 and the vibration damper 23. The coupling member 50 is connected to the magnet support body 21.

[Configuration 3] The vibration damper 23 is disposed between the magnet support body 21 and the magnet device body 10. The vibration damper 23 is a device that reduces vibration transmitted from the magnet support body 21 to the magnet device body 10.

The following effects can be obtained by [Configuration 3] described above. In [Configuration 1], the refrigerator support 40 and the magnet support 20 are coupled by the coupling member 50. Therefore, vibration of the refrigerator 31 and the refrigerator support 40 (vibrations of the beam B) are transmitted to the magnet support 20 through the coupling member 50. On the other hand, the superconducting magnet device 1 includes the vibration damper 23 of [Configuration 3]. Therefore, even if the vibration of the refrigerator 31 and the refrigerator support 40 (the vibration of the beam B) are transmitted to the magnet support body 21 through the coupling member 50, the vibration is hardly transmitted to the magnet device body 10. Therefore, the superconducting magnet device 1 can suppress the vibration that affects the measurement in the magnet device body 10 from being transmitted to the magnet device body 10. In the example of FIG. 1, the vibration damper 23 is connected to the lower surface 11a of the magnet device body 10, particularly, an outer periphery of the lower surface 11a, and is interposed between the lower surface 11a and the magnet support body 21 in the up-down direction. In this case, a structure including the magnet device body 10 and the magnet support 20 can be set compact in a radial direction (width direction).

On the other hand, in the example of FIG. 2, the vibration damper 23 is connected to the side surface 11b of the magnet device body 10, particularly, a lower part of the side surface 11b so as to protrude in the radial direction. The magnet support body 21 extends downward from the vibration damper 23 to the installation surface F. In this case, the structure including the magnet device body 10 and the magnet support 20 is less likely to fall, and the magnet device body 10 can be stably supported.

[Configuration 4] In the present embodiment, a plurality of coupling members 50 is provided. The plurality of coupling members 50 are disposed apart from each other in the up-down direction Z.

In [Configuration 4], the magnet support 20, the refrigerator support 40, and the plurality of coupling members 50 can be integrally coupled and fixed to each other. Accordingly, the rigidity of the magnet support 20, the refrigerator support 40, and the plurality of coupling members 50 as a whole can be improved (deformation can be suppressed). Therefore, the superconducting magnet device 1 can suppress vibration that affects measurement in the magnet device body 10.

### <Modifications>

The above embodiment may be variously modified. For example, modifications of the above embodiment may be variously combined. For example, the number of the components (including modifications) in the above embodiment may be changed, and some of the components do not have to be provided. Specifically, for example, the number of coupling members 50 and the like may be changed. For example, the arrangement of the components may be changed. For example, an inclusion relationship of the components may be variously changed. For example, a component described as a lower component included in a certain higher component is not required to be included in the higher component, and may be included in another component. Specifically, for example, the coupling member 50 may be a component of the refrigerant evaporation suppression device 30. For example, a plurality of members and parts different from each other may be described as one member and part. For example, what has been described as one member and part may be divided into a plurality of different members and parts. Specifically, for example, the refrigerator support body 41 may include a plurality of members (for example, columnar members). In this case, the coupling member 50 may be connected to each of a plurality of members constituting the refrigerator support body 41. For example, the components each may have only some of the characteristics (function, arrangement, shape, operation, and the like).

This application is based on Japanese Patent application No. 2023-065002 filed in Japan Patent Office on Apr. 12, 2023, the contents of which are hereby incorporated by reference.

Although the present invention has been fully described by way of example with reference to the accompanying drawings, it is to be understood that various changes and modifications will be apparent to those skilled in the art. Therefore, unless otherwise such changes and modifications depart from the scope of the present invention hereinafter defined, they should be construed as being included therein.

1. A superconducting magnet device comprising:
a magnet device body including a superconducting magnet;
a magnet support that supports the magnet device body such that the magnet device body is disposed above an installation surface;
a refrigerator that is disposed at a position away from the magnet device body and cools a refrigerant that cools the superconducting magnet;
a refrigerator support that supports the refrigerator from below such that the refrigerator is disposed above the installation surface; and
at least one coupling member that couples the refrigerator support and the magnet support at a position above the installation surface.

2. The superconducting magnet device according to claim 1, further comprising:
a refrigerant circulation pipe that is connected to the magnet device body and the refrigerator and through which the refrigerant passes, wherein
the refrigerator support supports the refrigerator such that the refrigerator is disposed at a height that allows the refrigerant condensed in the refrigerator to flow from the refrigerator into the magnet device body through the refrigerant circulation pipe by a weight of the refrigerant.

3. The superconducting magnet device according to claim 1, wherein
the magnet support includes:
a magnet support body to which the at least one coupling member is connected; and
a vibration damper that is disposed between the magnet support body and the magnet device body and reduces vibration transmitted from the magnet support body to the magnet device body.

4. The superconducting magnet device according to claim 1, wherein
the at least one coupling member includes a plurality of coupling members, and the plurality of coupling members are disposed apart from each other in an up-down direction.
